(19) United States
(12) Patent Application Publication
(10) Pub. No.: US 2026/0198256 A1
(43) Pub. Date: Jul. 9, 2026

(54) 3D IMAGING BY LIQUID IMMERSION WITH TILT AND/OR ROTATION

(71) Applicant: TOKYO ELECTRON LIMITED, Tokyo (JP)

(72) Inventors: Daniel FULFORD, Albany, NY (US); Anton DEVILLIERS, Albany, NY (US); Mark I. GARDNER, Austin, TX (US); H. Jim FULFORD, Marianna, FL (US)

(73) Assignee: TOKYO ELECTRON LIMITED, Tokyo (JP)

(21) Appl. No.: 19/010,740

(22) Filed: Jan. 6, 2025

(51) Int. Cl. H01L 21/67; G02B 21/33; H04N 13/254; H04N 23/56

(52) U.S. Cl. CPC H10P 72/0616; G02B 21/33; H04N 13/254; H04N 23/56

(57) ABSTRACT

A method of 3D imaging includes immersing an objective lens of a microscope at least partially in a liquid film formed on a wafer. The objective lens is spaced apart from the wafer. The microscope includes a light source configured to emit light of one or more wavelengths. A first image of a region within the wafer is captured using the one or more wavelengths. The wafer is reoriented relative to the region. The reorienting includes at least one of tilting the wafer or rotating the wafer. The reorienting is performed while keeping the objective lens at least partially immersed in the liquid film and spaced apart from the wafer. A second image of the region is captured using the one or more wavelengths.

### INCORPORATION BY REFERENCE

Aspects of the present disclosure are related to Applicant's co-pending application titled “3D IMAGING BY LIQUID IMMERSION” with Attorney Docket No. 554184US, which is incorporated herein by reference in its entirety.

### FIELD OF THE INVENTION

This disclosure relates generally to semiconductor processing and more specifically to wafer characterization and a system configured to perform wafer characterization.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Various techniques have been developed to characterize the semiconductor device elements formed on the substrate to monitor the manufacturing process as well as to evaluate the manufactured product.

### SUMMARY

The present disclosure relates to a method of 3D imaging and an imaging system.

According to aspect (1) of the disclosure, a method of 3D imaging is provided. The method includes immersing an objective lens of a microscope at least partially in a liquid film formed on a wafer. The objective lens is spaced apart from the wafer. The microscope includes a light source configured to emit light of one or more wavelengths. A first image of a region within the wafer is captured using the one or more wavelengths. The wafer is reoriented relative to the region. The reorienting includes at least one of tilting the wafer or rotating the wafer. The reorienting is performed while keeping the objective lens at least partially immersed in the liquid film and spaced apart from the wafer. A second image of the region is captured using the one or more wavelengths.

Aspect (2) includes the method of aspect (1), wherein the reorienting the wafer including tilting the wafer relative to the region using magnetically controlled movement.

Aspect (3) includes the method of aspect (2), wherein the wafer is on a wafer carrier including a first magnet. The wafer carrier is above a wafer chuck including a second magnet. At least one of the first magnet or the second magnet includes an electromagnet.

Aspect (4) includes the method of aspect (3), wherein the electromagnet includes separate electromagnetic units that are independent of each other. The tilting the wafer includes flowing different electrical currents through the separate electromagnetic units to create a magnetic field gradient along a horizontal direction parallel to a top surface of the wafer chuck.

Aspect (5) includes the method of aspect (3), further including moving the wafer toward or away from the objective lens by adjusting an electrical current through the electromagnet and capturing a third image of the region using the one or more wavelengths while the objective lens is at least partially immersed in the liquid film and spaced apart from the wafer.

Aspect (6) includes the method of aspect (3), wherein the first magnet includes a permanent magnet, and the wafer chuck is an electrostatic chuck or reverse electrostatic chuck.

Aspect (7) includes the method of aspect (1), wherein the reorienting the wafer includes tilting, rotating or both tiling and rotating the wafer relative to the region by a robotic shaft. The wafer is on a wafer carrier, and the wafer carrier is on the robotic shaft.

Aspect (8) includes the method of aspect (7), further including moving the wafer toward or away from the objective lens by moving the robotic shaft, and capturing a third image of the region using the one or more wavelengths while the objective lens is at least partially immersed in the liquid film and spaced apart from the wafer.

Aspect (9) includes the method of aspect (7), wherein the robotic shaft is offset from a center of the wafer.

Aspect (10) includes the method of aspect (7), wherein the wafer carrier is movably attached to the robotic shaft, and the wafer carrier is fixedly held on the robotic shaft during the reorienting the wafer.

Aspect (11) includes the method of aspect (7), wherein the wafer carrier includes at least one selected from the group consisting of a wafer pin, a clamp and a vacuum cavity, configured to hold the wafer. The robotic shaft includes at least one selected from the group consisting of a wafer pin, a clamp and a vacuum cavity, configured to hold the wafer carrier.

Aspect (12) includes the method of aspect (1), the region is offset from a center of the wafer.

Aspect (13) includes the method of aspect (1), a center of the wafer is located in the region.

Aspect (14) includes the method of aspect (1), wherein the wafer includes a dielectric material and a structure embedded in the dielectric material. The light of one or more wavelengths is configured to penetrate the dielectric material and reach the structure. The structure includes a top structure and a bottom structure. The top structure is configured to block the light of one or more wavelengths. The top structure is wider than the bottom structure when viewed from above the top structure.

Aspect (15) includes the method of aspect (1), further including forming the liquid film by immersing the wafer in a liquid contained within a housing.

Aspect (16) includes the method of aspect (1), further including forming the liquid film by continuously dispensing a liquid onto the wafer to keep the objective lens at least partially immersed in the liquid film.

Aspect (17) includes the method of aspect (1), wherein the liquid film completely covers the wafer.

Aspect (18) includes the method of aspect (1), wherein the liquid film partially covers the wafer.

Aspect (19) includes the method of aspect (1), wherein the one or more wavelengths consists of a single wavelength.

Aspect (20) includes the method of aspect (1), wherein the one or more wavelengths includes a plurality of discrete wavelengths.

Aspect (21) includes the method of aspect (1), wherein the one or more wavelengths includes a range of continuous wavelengths.

Aspect (22) includes the method of aspect (1), wherein the liquid film includes water, oil or both.

Aspect (23) includes the method of aspect (1), wherein the liquid film includes a layer of water.

Aspect (24) includes the method of aspect (1), further including moving the microscope by a robotic arm.

According to aspect (25) of the disclosure, an imaging system is provided. The imaging system includes a wafer carrier configured to receive a wafer and including a first magnet, a wafer chuck including a second magnet, and a microscope including a light source configured to emit light of one or more wavelengths, optics configured to direct the light to the wafer, and a detector configured to image the wafer. At least one of the first magnet or the second magnet includes an electromagnet. The optics include an objective lens configured for at least partial immersion in a liquid film formed on the wafer. A liquid supply mechanism is configured to form the liquid film between the wafer and the objective lens. The detector is configured to image a region within the wafer while the objective lens is at least partially immersed in the liquid film and spaced apart from the wafer. The electromagnet includes separate electromagnetic units that are independent of each other. The separate electromagnetic units are configured to receive separate electrical currents to create a magnetic field gradient along a horizontal direction parallel to a top surface of the wafer chuck to tilt the wafer relative to the region.

Aspect (26) includes the imaging system of aspect (25), wherein the electromagnet is configured to move the wafer toward or away from the objective lens by receiving an electrical current to attract the wafer carrier to the wafer chuck or repel the wafer carrier from the wafer chuck while the wafer remains on the wafer carrier.

Aspect (27) includes the imaging system of aspect (25), wherein the liquid supply mechanism includes a liquid dispenser configured to continuously dispense a liquid at the wafer to maintain the liquid film on the wafer.

Aspect (28) includes the imaging system of aspect (27), wherein the liquid supply mechanism includes a container configured to collect the liquid leaving the wafer and provide the liquid for the liquid dispenser.

Aspect (29) includes the imaging system of aspect (25), wherein the liquid supply mechanism includes a housing configured to contain a liquid to form the liquid film on the wafer, and the liquid is stationary.

Aspect (30) includes the imaging system of aspect (25), wherein the detector is configured to capture a series of images for a given location on the wafer at a series of distances between the wafer and the objective lens as the wafer carrier moves the wafer toward or away from the objective lens. The imaging system further includes a controller that is configured to receive the series of images and create a three-dimensional rendering of the wafer at the given point location for defect identification.

According to aspect (31) of the disclosure, an imaging system is provided. The imaging system includes a wafer carrier configured to receive a wafer, a robotic shaft below the wafer carrier, and a microscope including a light source configured to emit light of one or more wavelengths, optics configured to direct the light to the wafer, and a detector configured to image the wafer. The optics include an objective lens configured for at least partial immersion in a liquid film formed on the wafer. A liquid supply mechanism is configured to form the liquid film between the wafer and the objective lens. The detector is configured to image a region within the wafer while the objective lens is at least partially immersed in the liquid film and spaced apart from the wafer. The robotic shaft is configured to reorient the wafer relative to the region, by tilting the robotic shaft, rotating the robotic the robotic shaft or both so that the wafer tilts, rotates or both tilts and rotates around the region.

Aspect (32) includes the imaging system of aspect (31), wherein the robotic shaft is configured to move the wafer toward or away from the objective lens.

Aspect (33) includes the imaging system of aspect (31), wherein the wafer carrier is movably attached to the robotic shaft, and the wafer carrier is fixedly held on the robotic shaft during the reorienting the wafer.

Aspect (34) includes the imaging system of aspect (31), wherein the wafer carrier includes at least one selected from the group consisting of a pin, a clamp and a vacuum cavity, configured to hold the wafer. The robotic shaft includes at least one selected from the group consisting of a pin, a clamp and a vacuum cavity, configured to hold the wafer carrier.

Aspect (35) includes the imaging system of aspect (31), wherein the liquid supply mechanism includes a liquid dispenser configured to continuously dispense a liquid at the wafer to form the liquid film on the wafer.

Aspect (36) includes the imaging system of aspect (35), wherein the liquid supply mechanism includes a container configured to collect the liquid leaving the wafer and provide the liquid for the liquid dispenser.

Aspect (37) includes the method of aspect (31), wherein the liquid supply mechanism includes a housing configured to contain a liquid to form the liquid film on the wafer, and the liquid is stationary.

Aspect (38) includes the imaging system of aspect (31), wherein the detector is configured to capture a series of images for a given location on the wafer at a series of distances between the wafer and the objective lens as the wafer carrier moves the wafer toward or away from the objective lens. The imaging system further includes a controller that is configured to receive the series of images and create a three-dimensional rendering of the wafer at the given point location for defect identification.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A shows a vertical cross-sectional view of an imaging system in accordance with some embodiments of the present disclosure.

FIG. 1B shows a vertical cross-sectional view of an imaging system in accordance with some embodiments of the present disclosure.

FIG. 1C shows a vertical cross-sectional view of an imaging system in accordance with some embodiments of the present disclosure.

FIG. 2 shows a flow chart of an imaging process, in accordance with some embodiments of the present disclosure.

FIGS. 3A, 3B and 3C show vertical cross-sectional views of an imaging system at various intermediate steps of imaging, in accordance with some embodiments of the present disclosure.

FIG. 4A shows a vertical cross-sectional view of an imaging system in accordance with some embodiments of the present disclosure.

FIG. 4B shows a vertical cross-sectional view of an imaging system in accordance with some embodiments of the present disclosure.

FIG. 4C shows a vertical cross-sectional view of an imaging system in accordance with some embodiments of the present disclosure.

FIG. 4D shows a vertical cross-sectional view of an imaging system in accordance with some embodiments of the present disclosure.

FIG. 5 shows a flow chart of an imaging process, in accordance with some embodiments of the present disclosure.

FIGS. 6A, 6B and 6C show vertical cross-sectional views of an imaging system at various intermediate steps of imaging, in accordance with some embodiments of the present disclosure.

FIGS. 7A, 7B and 7C show vertical cross-sectional views of a wafer at various intermediate steps of imaging, in accordance with some embodiments of the present disclosure.

FIG. 8 shows a flow chart of an imaging process, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

A numerical range represented by “to” includes numerical values at both ends, unless specified otherwise.

Three-dimensional (3D) integration, i.e. the vertical stacking of multiple devices, aims to overcome scaling limitations experienced in planar devices by increasing transistor density in volume rather than area. For example, device stacking has been successfully demonstrated and implemented by the flash memory industry with the adoption of 3D NAND. Nevertheless, 3D characterization of semiconductor structures has been elusive.

The present disclosure provides a method and a system for defect analysis in circuit elements by employing an enhanced resolution 3D defect imaging system. Techniques herein use a liquid film at the wafer surface, a mechanical or magnetic chuck for elevation adjustments, and at least one wavelength for defect classification. The method involves scanning while elevating the wafer using a magnetic field at various heights, and moving the chuck in minute increments (e.g. one-nanometer increments) to create a holographic 3D defect image. A differential pressure mechanism (e.g. based on fluid or obtained by gate or vacuum) enhances the microscope's resolution, and the 3D defect can be inserted into an artificial intelligence (AI) engine for further analysis. This efficient and non-destructive testing approach allows for comprehensive 3D analysis of circuit elements, with applications in transistors, memory cells, and other circuit elements, with significant improvements in 3D defect classification and analysis.

According to aspects of the present disclosure, a liquid film can be placed on a wafer surface to form an immersion layer which can be one or more layers to enhance the resolution of a microscope. The liquid film between the optics and the wafer is useful in at least two aspects: (1) to reduce the DOF; and (2) to keep the wafer cool to avoid heating and degrading the device properties. Due to the liquid film, DOF (depth of focus) of the microscope can be smaller than feature size. DOF need to be smaller than the size of the defect in order to obtain the 3D image; otherwise only a 2D image is available. Additionally, process control cooling can maintain the substrate at a low temperature, thus allowing for all electromagnetic spectrum wavelengths.

The wafer chuck can be elevated to different heights to augment 3D layering by using magnets or controlling a gas pressure. A multiple wavelength tool can be used to classify defects, utilizing visible and/or non-visible spectra or a single wavelength. An augmented chuck design is configured to tilt the wafer while performing scans whereas conventional techniques do not exist to identify or classify defect types and to drill down with a 3D probe. The wafer chuck may be moveable at ±1 nm increments in all directions (e.g. in the X, Y and/or Z directions) to make a holographic 3D defect image e.g. by capturing an image at each location.

Therefore, techniques herein allow to look at 3D analysis of the entirety of a transistor, a memory cell or any circuit element. Techniques herein enable a non-destructive 3D test for defect classification. The 3D defect can be inserted into an AI engine for further analysis. Techniques herein also enable a drill-down metrology, a drill-down-and-tomography combination, drill-down analysis features, drill-down AI integration and optimization, a hyperspectral imaging system, etc. Techniques herein can further be utilized to enhance the defect analysis of an existing tool by providing a method of using a 3D microscope for defect analysis hyper spectrum based on fluorescent signal analysis for defects to improve classification.

The present disclosure provides a system and a method for defect analysis in a wafer. The system includes a wafer chuck designed to hold the wafer, a liquid film at the wafer/imaging optical interface, and a set of magnets for 3D layering. The wafer chuck can tilt and/or rotate the wafer during scanning and is movable at nanometer increments to generate a holographic 3D defect image. A hyperspectral imaging device generates images in multiple wavelengths (e.g. continuous spectral bands with fine wavelength resolution) to classify defects. This approach allows for a non-destructive 3D test for defect classification, enabling the 3D analysis of entire transistors, memory cells, or any circuit elements. Techniques herein provide an efficient and effective solution for defect analysis and offer significant advantages in the field of semiconductor manufacturing.

Moreover, the capability of tilting, rotating or both tilting and rotating simultaneously enables the characterization of a 3D object that contains a wider top region than bottom features. Indeed, all geometries can be classified without particular limitations.

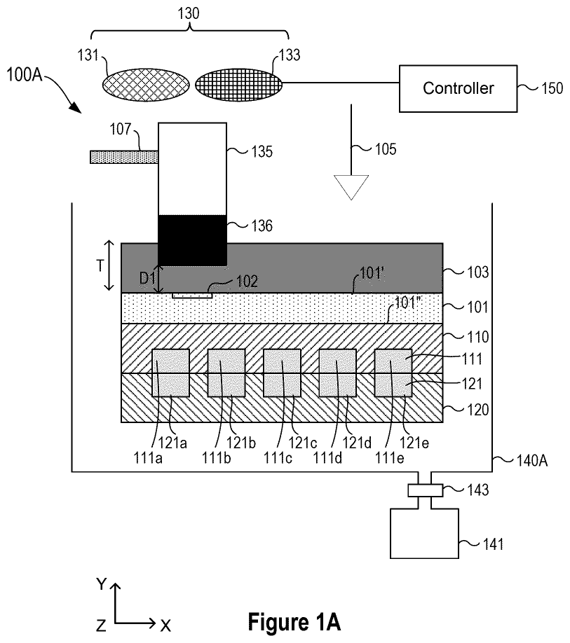

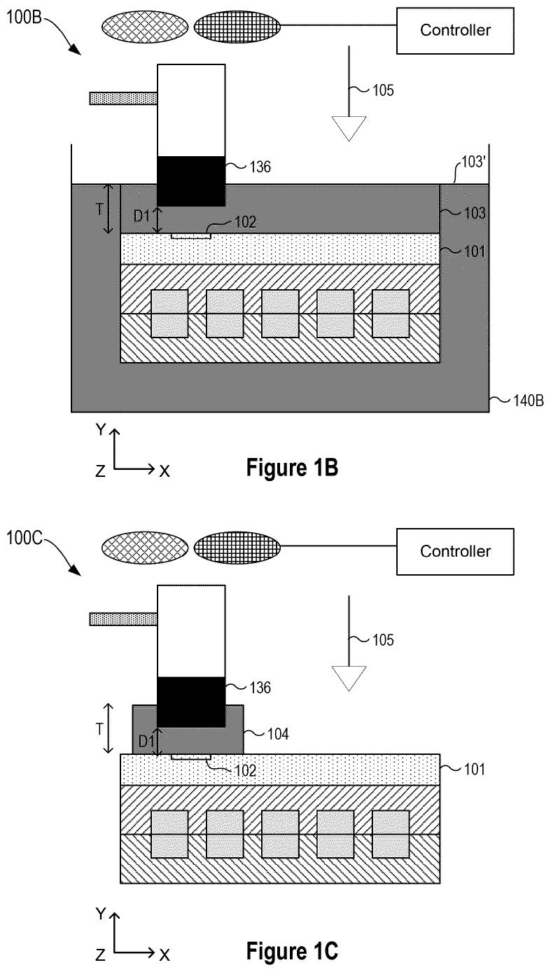

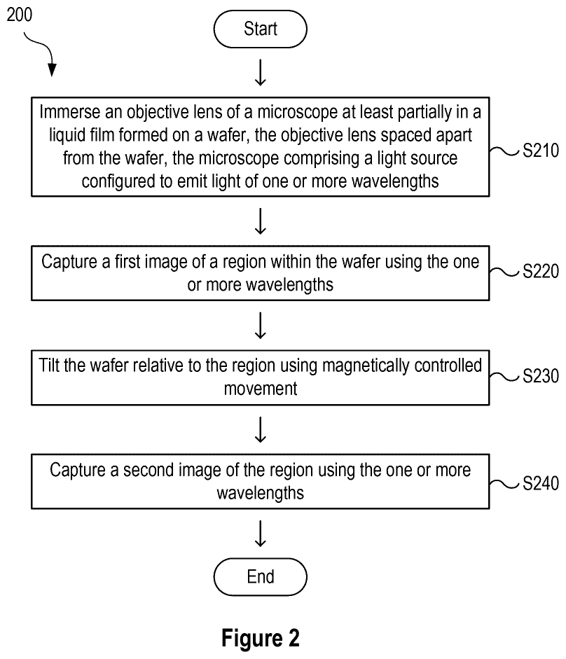

FIG. 1A shows a vertical cross-sectional view of an imaging system (hereinafter referred to as a system 100A) in accordance with some embodiments of the present disclosure. The system 100A includes a housing 140A and a wafer carrier 110 positioned in the housing 140A and configured to receive a wafer 101. A wafer chuck 120 is placed below the wafer carrier 110. The wafer carrier 110 and the wafer chuck 120 are configured to move the wafer 101 toward or away from an objective lens 136 of a microscope 130 using magnetically controlled movement, for example in a vertical direction (e.g. the Z direction) parallel to a gravity direction by magnetic forces. It should be understood that the vertical direction or the Z direction may not be perfectly parallel to the gravity direction and may be at an angle with the gravity direction. The angle is not particularly limited and can for example be 0°-30° e.g. 0°, 1°, 2°, 3°, 5°, 10°, 20°, 30° or any values therebetween.

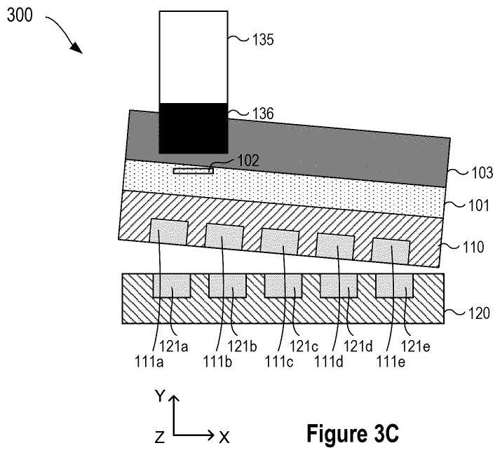

As illustrated, the wafer carrier 110 can include one or more first magnets 111 e.g. first magnets 111a, 111b, 111c, 111d and 111e as shown. The wafer chuck 120 can include one or more second magnets 121 e.g. second magnets 121a, 121b, 121c, 121d and 121e as shown. At least one of the one or more first magnets 111 or the one or more second magnets 121 is an electromagnet, whose magnetic field can be adjusted by adjusting an electrical current, which passes through the electromagnet, in order to move the wafer 101 up or down in the Z direction, which will be further explained in detail in FIGS. 3A-3C.

When the one or more first magnets 111 and/or the one or more second magnets 121 include a plurality of electromagnets, the plurality of electromagnets can be controlled together (e.g. electrically connected to a common electrical source to receive a same electrical current). Alternatively or additionally, the plurality of electromagnets may include separate electromagnetic units (e.g. 121a-121e) that are independent of each other, and the separate electromagnetic units are configured to receive separate electrical currents to create a magnetic field gradient along a horizontal direction (e.g. the X direction) parallel to a top surface of the wafer chuck 115 to tilt the wafer 101 relative to, or around, a region 102 within the wafer 101, which will be further explained in detail in FIGS. 3A-3C.

In some embodiments, the first magnets 111a-111e are permanent magnets while the second magnets 121a-121e are electromagnets. For instance, the wafer chuck 120 can be an electrostatic chuck or reverse electrostatic chuck. In some embodiments, the first magnets 111a-111e are electromagnets while the second magnets 121a-121e are permanent magnets. In some embodiments, the first magnets 111a-111e and the second magnets 121a-121e are all electromagnets. In some embodiments, the first magnets 111a-111e include both at least one permanent magnet and at least one electromagnet. In some embodiments, the second magnets 121a-121e include both at least one permanent magnet and at least one electromagnet.

The system 100A can also include a liquid dispenser 105 that is configured to continuously or non-stop dispense a liquid (e.g. 103′ in FIG. 1B) at the wafer 101 to form a liquid film 103 on the wafer 101 during operation. The liquid dispenser 105 can be in the form of a nozzle, a syringe, a sprayer, a pipe or the like. By controlling the dispensing rate (e.g. the volume of the liquid per unit time), a thickness of the liquid may be steadily formed over a fraction or preferably the entirety of the wafer 101 to form the liquid film 103 that may or may not be uniform in the XY plane. A position of the liquid dispenser 105 is not particularly limited, and any number of liquid dispensers can be used. For instance, two or more liquid dispensers (e.g. 105) can be positioned around a periphery of the optics 135.

An excessive amount (not shown) of the liquid leaving the wafer 101 can be collected in the housing 140A. For instance, the housing 140A can include a valve 143 and a container 141 for storing the excessive amount of the liquid, which may be directed back to the liquid dispenser 105 and dispensed at the wafer 101 for recycling purposes.

The chemical composition of the liquid (e.g. 103′ in FIG. 1B) is not particularly limited and can include, but is not limited to, water and oil such as a synthetic immersion oil, a cedarwood oil, a silicone oil, glycerol or the like. The liquid film 103 can include one or more layers depending on the specific applications. Preferably, the liquid film 103 is a single layer of water. Alternatively, the liquid can be an aqueous solution as long as the solute(s) therein does not react with the wafer 101 or dope the wafer 101.

The system 100A further includes the microscope 130 that includes a light source 131 configured to emit light of one or more wavelengths, optics 135 configured to direct the light to the wafer 101, and a detector 133 configured to image the wafer 101 at a plurality of vertical positions e.g. at different Z heights or Z positions. Particularly, the optics 135 can include the objective lens 136 that is at least partially immersed in the liquid film 103. The detector 133 can be configured to capture a series of images for a given location on the wafer 101 at a series of distances between the wafer 101 and the objective lens 136 as the wafer carrier 110 moves the wafer 101 toward or away from the objective lens 136. The optics 135 can be in the form of an optical tower or optical tower stand. A robotic arm 107 can be configured to move the microscope 130 in the X, Y and/or Z directions.

The one or more wavelengths are not particularly limited and may include the entire electromagnetic spectrum including gamma rays, X-rays, ultraviolet light, visible light, infrared light, microwaves and radio waves. Preferably, the one or more wavelengths include ultraviolet light, visible light and/or infrared light. Preferably, the one or more wavelengths include visible light and/or infrared light. Preferably, the one or more wavelengths include infrared light. Additionally, the one or more wavelengths can include a range of continuous wavelengths (e.g. a continuous spectral band), a plurality of discrete wavelengths or a single wavelength during operation.

While shown to have a thickness, the region 102 can have a negligible thickness compared to a thickness of the wafer 101. For instance, the region 102 can represent a (virtual) image plane of the microscope 130. The region 102 can have any X and Y positions within the wafer 101 without particular limitations. In some embodiments, the region 102 is offset from a center of the wafer 101. In some embodiments, the center of the wafer 101 is located in the region 102. In other words, the region 102 may or may not be offset from the center of the wafer 101.

The region 102 can have any Z position within the wafer 101 without particular limitations. In some embodiments, the wafer 101 includes dielectric material(s) at or near a top surface 101′ of the wafer 101, and the one or more wavelengths include at least an infrared wavelength that can penetrate the dielectric material(s). As a result, a relatively large depth (e.g. the entirety of the depth) of the wafer 101 can be imaged. In some embodiments, the wafer 101 includes metal material(s) at or near the top surface 101′, and the one or more wavelengths may not penetrate the metal material(s). Accordingly, a relatively small depth of the wafer 101 can be imaged. Preferably, the region 102 is closer to the top surface 101′ of the wafer 101 than a bottom surface 101″ of the wafer 101. For instance, the region 102 may be below the top surface 101′ of the wafer 101 by 0-1000 nm e.g. 0 nm, 1 nm, 5 nm, 10 nm, 20 nm, 50 nm, 100 nm, 200 nm, 500 nm, 1000 nm or any values therebetween. In the case of 0 nm, the region 102 is at the top surface 101′ of the wafer 101.

Tilting the wafer 101 relative to or around the region 102 includes tilting the wafer 101 around any point of the region 102 such as a boundary point or an inner point or around any axis that passes through the region 102. Preferably, the wafer 101 is tilted around a central point or a central axis of the region 102. Note that various features in the figures of the present disclosure are not drawn to scale. In practice, the region 102 is relatively small compared to the wafer 101 so that the region 102 as a whole may be treated as a point or an axis for tilting.

The wafer 101 can include any materials (e.g. metals, dielectrics, semiconductors, etc.) formed on a substrate. These materials can form any circuit elements including, but not limited to, a transistor, a resistor, a capacitor, a memory cell, a peripheral circuit, an analog circuit, a digital circuit, a radio frequency circuit and/or any other circuit element. The microscope 130 can be used to image any part of the wafer 101, including the aforementioned circuit elements or defects during manufacturing. The present disclosure will be focused on defect analysis for illustrative purposes. Accordingly, the system 100A may also be referred to as a 3D defect imaging system.

“Substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only. The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

A distance D1 between a bottom of the objective lens 136 and a top of the liquid film 103 is not particularly limited and can be 0.001 mm-2 mm e.g. 0.001 mm, 0.01 mm, 0.02 mm, 0.03 mm, 0.05 mm, 0.07 mm, 0.1 mm, 0.2 mm, 0.3 mm, 0.5 mm, 0.7 mm, 1 mm, 2 mm or any values therebetween. A thickness T of the liquid film 103 is not particularly limited and can be 0.001 mm-50 mm e.g. 0.001 mm, 0.01 mm, 0.1 mm, 0.5 mm, 1 mm, 2 mm, 5 mm, 10 mm, 20 mm, 50 mm, or any values therebetween. T is equal to or larger than D1 and is preferably larger than D1. Both T and D1 can be adjusted based on the type and/or size of a defect to be analyzed.

The system 100A can optionally include a controller 150. The controller 150 may optionally be connected to a memory storage unit and a user interface (all not shown). Various operations can be executed via the user interface. Various data and parameter settings can be stored in the memory storage unit.

The controller 150 may be coupled to one or more components of the system 100A to receive inputs from and provide outputs to the one or more components. For example, the controller 150 can be configured to receive image data from the detector 133 and show the image data on the user interface. The controller 150 can control the detector 133 to capture images of the wafer 101 during a continuous scan while the wafer 101 and/or the microscope 130 are moving in the X, Y and/or Z directions. For example, the controller 150 can be configured to send commands to the detector 133 for the detector 133 to capture a series of images for a given location on the wafer 101 at a series of distances between the wafer 101 and the objective lens 136 as the wafer carrier 110 moves the wafer 101 toward or away from the objective lens 136. The controller 150 can further be configured to receive the series of images from the detector 133 and create a three-dimensional rendering of the wafer 101 at the given point location for defect identification. The controller 150 can also be coupled to the robotic arm 107 to receive positional information of the microscope 130 from the robotic arm 107 and provide commands to move the robotic arm 107 in order to move the microscope 130. The controller 150 can further be coupled to the wafer carrier 110 and/or the wafer chuck 120 to control an electrical current(s) that passes through the aforementioned electromagnet(s) to move the wafer 101 up or down. The controller 150 can further be coupled to the liquid dispenser 105 and/or the container 141 to regulate liquid dispensing and/or recycling. Additionally, the controller 150 can be configured to adjust knobs and control settings for the one or more components of the system 100A as mentioned above. Of course such adjustments can be manually made as well.

The controller 150 can be implemented in a wide variety of manners. In one example, the controller 150 is a computer. In another example, the controller 150 includes one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a proscribed plasma process recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

In some embodiments, the system 100A represents a magnetic chuck option with defect selection in the X, Y and Z directions using a magnetic field with tilt. A dual magnetic carrier-chuck system can enable the magnetic field in the wafer carrier 110 and the wafer chuck 120 to interact with a magnetic force of attraction or repulsion to move the wafer 101 in the Z direction. A variable magnetic field across the wafer 101 can be obtained to tilt the wafer 101 while simultaneously elevating the wafer 101 at different heights for 3D layering.

An optical tower (e.g. 135) can include at least one lens (e.g. 136) and a light source (e.g. 131) such as lasers capable of emitting the entire electromagnetic spectrum frequencies. The optical tower can be fixed while the wafer 101 is allowed to scan in the X, Y and Z as well as theta (angular) directions. Alternatively, the microscope 130 can scan in the XY plane while the wafer 101 does not move in the XY plane. Of course, the microscope 130 and the wafer 101 can both scan in the XY plane together.

Any type of magnetic field generation can be used. For instance, the magnetic field can be modulated to increase or decrease magnetic regions in different states using a split chuck magnetic design. The optical tower can penetrate into the liquid film 103 above the wafer 101 at different Z heights to create a 3D image. The magnetic field is changed to obtain different Z height locations while scanning in the XY plane.

In some embodiments, the system 100A can operate in a continuous scan and image capturing mode. For instance, the microscope 130 can be used to capture a series of images, while the wafer 101 is tilted, rotated and/or moved in ±1 nm increments in the X, Y and/or Z directions, in order to create a 3D defect image. The series of images can be input into the controller 150 which will then analyze and process the series of images. For example, the controller 150 may include an artificial intelligence (AI) engine or algorithm to create a 3D defect image, which can be used as a non-destructive test for defect classification. The controller 150 may further be used to create a 3D defect map of the wafer 101. Defects are then categorized into a library with information such as wafer location, process steps, and 3D signature. Using iterations of AI, defects can thus be identified and eliminated in a non-destructive fashion for continuous process improvement and yield enhancement.

FIG. 1B shows a vertical cross-sectional view of an imaging system (hereinafter referred to as a system 100B) in accordance with some embodiments of the present disclosure. The embodiment of the system 100B is similar to the embodiment of the system 100A. Note that similar or identical components are labeled with similar or identical numerals in the present disclosure unless specified otherwise. Descriptions that have been provided once before will be omitted for simplicity purposes.

As illustrated, the system 100B includes a housing 140B. The liquid dispenser 105 can be used to fill the housing 140B with a liquid 103′ to form the liquid film 103 that is uniform in the XY plane. It should be understood that boundaries are shown between the liquid 103′ and the liquid film 103 merely for illustrative purposes. As the liquid film 103 is part of the liquid 103′, such boundaries do not exist in actuality. Alternatively or additionally, the liquid 103′ can be filled into the housing 140B manually.

FIG. 1C shows a vertical cross-sectional view of an imaging system (hereinafter referred to as a system 100C) in accordance with some embodiments of the present disclosure. The embodiment of the system 100C is similar to the embodiment of the system 100A. Herein, a fraction (or a localized area, or a pattern) of the wafer 101 is covered with a liquid film 104. Accordingly, a housing (e.g. 140A or 140B) and/or the liquid dispenser 105 may or may not be necessary. The liquid film 104 can be replaced or replenished during an imagine process to maintain optical resolution. The liquid film 104 can include water or oil as discussed above. Preferably, the liquid film 104 includes a liquid that has a high surface tension such as water. Accordingly, the liquid film 104 can be in the form of a droplet or droplets merged together.

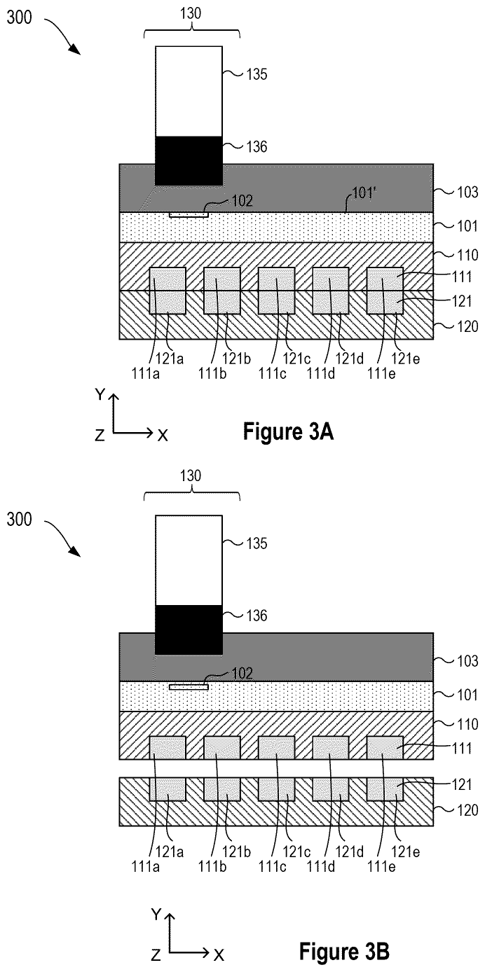

FIG. 2 shows a flow chart of an imaging process 200, in accordance with some embodiments of the present disclosure. At step S210, an objective lens of a microscope is immersed at least partially in a liquid film formed on a wafer. The objective lens is spaced apart from the wafer. The microscope includes a light source configured to emit light of one or more wavelengths. At step S220, a first image of a region within the wafer is captured using the one or more wavelengths. At step S230, the wafer is tilted relative to or around the region using magnetically controlled movement. At step S240, a second image of the region is captured using the one or more wavelengths.

FIGS. 3A, 3B and 3C show vertical cross-sectional views of an imaging system (hereinafter referred to as a system 300) at various intermediate steps of imaging, in accordance with some embodiments of the present disclosure. The system 300 can be the system 100A, 100B, 100C or the like. When the system 300 is the system 100A or 100B, some components (e.g. 107, 150, 140A/140B, 131 and 133) are omitted for simplicity purposes. Additionally, it should be understood that the imaging processes described in FIGS. 3A-3C using the liquid film 103 for illustration purposes are also applicable to the system 100C wherein the liquid film 104 is used.

In FIG. 3A, the wafer carrier 110 and the wafer chuck 120 are in contact with each other. The wafer carrier 110 and the wafer chuck 120 may have magnetic attraction or no magnetic force between each other. The microscope 130 can capture a first image of the region 102 of the wafer 101. As discussed earlier, the region 102 may be below the top surface 101′ of the wafer 101 by 0-1000 nm, and the present disclosure will be focused on defect analysis for illustrative purposes so the system 300 may also be referred to as a 3D defect imaging system.

In FIG. 3B, the wafer chuck 120 and the microscope 130 are stationary while the wafer carrier 110 is elevated in the Z direction using magnetically controlled movement. As a result, the region 102 imaged by the microscope 130 (or the image plane of the microscope 130) is relatively “moved” down, and the microscope 130 can capture a second image of the wafer 101 at a different Z position. The magnetically controlled movement can be tuned so that the wafer 101 can move at ±1 nm increments in the Z direction for the microscope 130 to image. As explained earlier, at least one of the one or more first magnets 111 or the one or more second magnets 121 is an electromagnet, whose magnetic field can be adjusted by adjusting an electrical current, which passes through the electromagnet, in order to move the wafer 101 up or down in the Z direction.

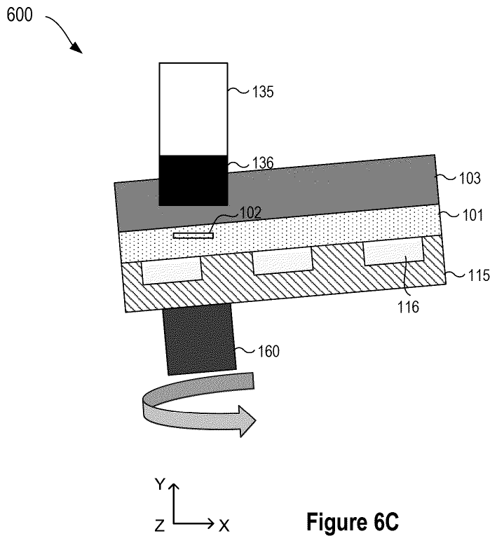

In FIG. 3C, the wafer 101 is tilted relative to or around the region 102 using magnetically controlled movement, and the microscope 130 can capture a third image of the wafer 101 at a tilted angle relative to the XY plane. The tilted angle is not particularly limited and can be larger than 0° and smaller than 90° e.g. 1°, 2°, 5°, 10°, 15°, 20°, 30°, 45°, 60°, 70°, 80°, 89° or any values therebetween. While shown to be tilted with the left part higher than the right part, it should be understood that the left part can be tilted to be lower than the right part as well, similar to FIG. 6C.

In some embodiments, the first magnets 111a-111e and the second magnets 121a-121e are all electromagnets. Each of the first magnets 111a-111e and the second magnets 121a-121e can include a respective electromagnetic unit, resulting in a plurality of electromagnetic units that are independent of each other, and the plurality of electromagnetic units are configured to receive separate electrical currents to create a magnetic field gradient along the X direction to tilt the wafer 101. In some embodiments, the first magnets 111a-111e are permanent magnets while the second magnets 121a-121e are independent electromagnetic units for creating the magnetic field gradient. In some embodiments, the first magnets 111a-111e are independent electromagnetic units for creating the magnetic field gradient while the second magnets 121a-121e are permanent magnets.

The wafer 101 may be further tilted by adjusting the magnetically controlled movement by adjusting the electrical currents passing through the independent electromagnetic units. The wafer 101 may also be further moved up or down by adjusting the magnetically controlled movement. The wafer 101 may further be tilted around a different region; or rather, the region 102 may be moved to a different location by moving the wafer 101 and/or the microscope 130 laterally in the XY plane. The microscope 130 can capture additional images of the wafer 101 at various X, Y and Z positions as well as various tilted angles.

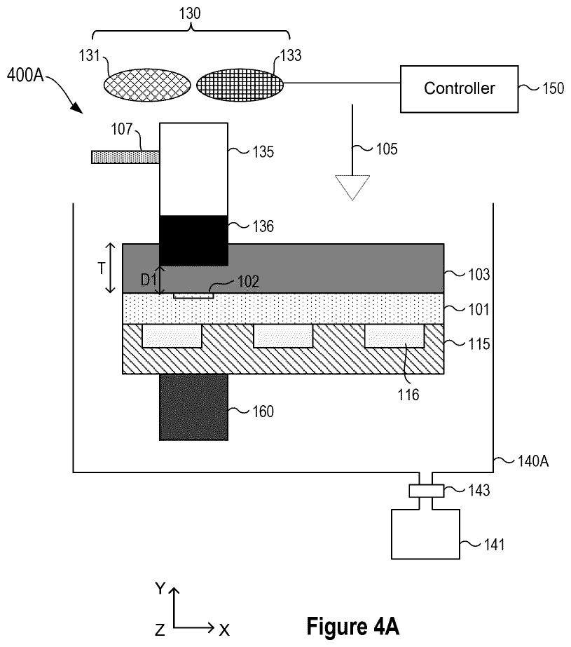

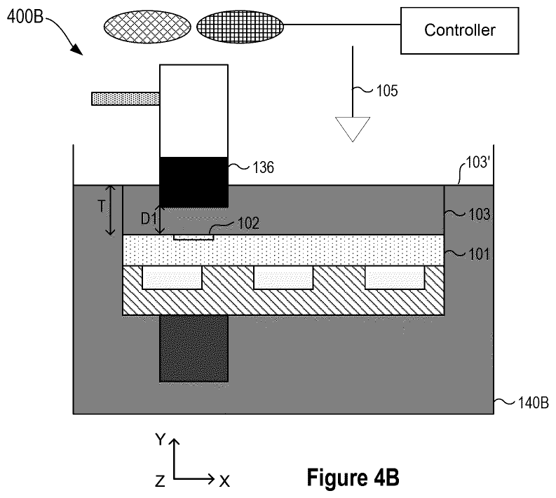

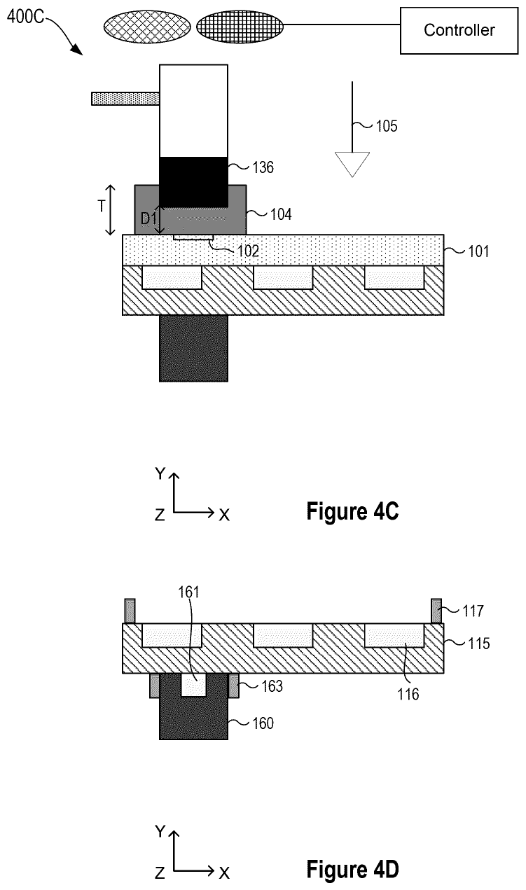

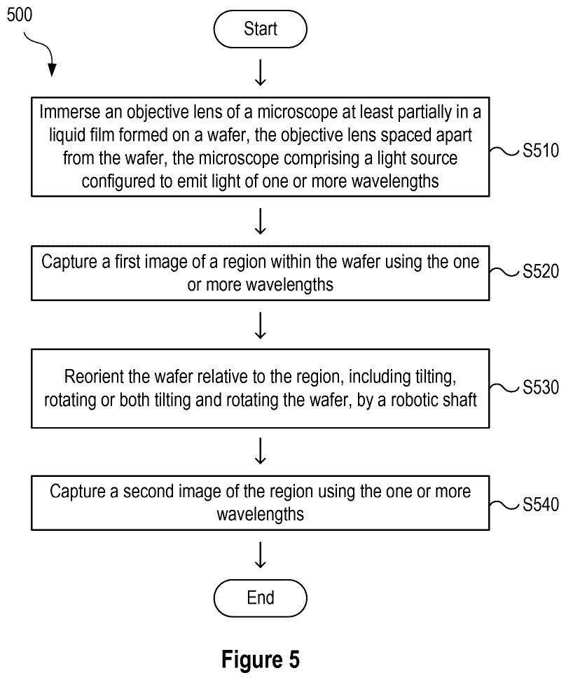

FIG. 4A shows a vertical cross-sectional view of an imaging system (hereinafter referred to as a system 400A) in accordance with some embodiments of the present disclosure. The embodiment of the system 400A is similar to the embodiment of the system 100A. Herein, the system 400A includes a wafer carrier 115 and a robotic shaft 160. The wafer carrier 115 can include vacuum cavities 116 and is configured to hold the wafer 101 on the wafer carrier 115 by creating vacuum via the vacuum cavities 116. The robotic shaft 160 may pass through a center of the wafer 101 or be offset from the center of the wafer 101. The robotic shaft 160 may have any shape or size. The robotic shaft 160 can be smaller than, equal to or larger than the wafer carrier 115 in the XY plane.

The robotic shaft 160 can be configured to reorient the wafer 101 by tilting, rotating or both tiling and rotating the wafer 101 relative to or around the region 102 by tilting, rotating or both tiling and rotating the robotic shaft 160, which will be further explained in detail in FIGS. 6A-6C. The wafer carrier 115 can be fixedly held on the robotic shaft 160, during the reorienting the wafer 101, by at least one vacuum cavity 161 and/or components 163 such as pins, clamps and/or the like for example as shown in FIG. 4D. Similarly, the wafer 101 can be held on the wafer carrier 115, during the reorienting the wafer 101, by the vacuum cavities 116 and/or components 117 such as pins, clamps and/or the like. It should be understood that the wafer carrier 110 can also include the components 117 such as pins, clamps and/or the like to hold the wafer 101.

The wafer carrier 115 can be movably attached to the robotic shaft 160 when not in operation. For instance, the components 163 may be installed on linear rails/guides such as a linear XY stage. Alternatively or additionally, the system 400A may include a plurality of the components 163 positioned at different X and Y locations of the wafer carrier 115. Additionally, the controller 150 may be coupled to the robotic shaft 160 and/or the wafer carrier 115 to receive inputs from and provide outputs to the robotic shaft 160 and/or the wafer carrier 115. Particularly, the controller 150 can control the motion of the robotic shaft 160 and/or the wafer carrier 115.

Tilting/rotating the wafer 101 relative to or around the region 102 includes tilting/rotating the wafer 101 around any point of the region 102 such as a boundary point or an inner point or around any axis that passes through the region 102. Preferably, the wafer 101 is tilted/rotated around a central point of the region 102. Note that various features in the figures of the present disclosure are not drawn to scale. In practice, the region 102 is relatively small compared to the wafer 101 so that the region 102 as a whole may be treated as a point or an axis for tilting/rotating.

In some embodiments, the system 400A represents a mechanical chuck option enabled by vacuum attraction and repulsion, with tilt and/or rotation. Using a tilt axis or a tilt point can allow to view images where a top surface of a 3D defect may have an overhang, thus revealing more 3D features of the defects. Combing both tilt and rotation can sweep the wafer 101 three hundred and sixty degrees while simultaneously changing the Z height and tilt.

An optical tower (e.g. 135) can include at least one lens (e.g. 136) and a light source (e.g. 131) such as lasers capable of emitting the entire electromagnetic spectrum frequencies. The optical tower can be fixed while the wafer 101 is allowed to scan in the X, Y and Z as well as theta (angular) directions. Alternatively, the microscope 130 can scan in the XY plane while the wafer 101 does not move in the XY plane. Of course, the microscope 130 and the wafer 101 can both scan in the XY plane together. No magnetic chuck is required for this option. This option uses vacuum attraction (e.g. vacuum in the vacuum cavities 119) to attach the wafer 101 to the wafer carrier 115 while the wafer 101 is elevated, tilted and/or rotated.

FIG. 4B shows a vertical cross-sectional view of an imaging system (hereinafter referred to as a system 400B) in accordance with some embodiments of the present disclosure. The embodiment of the system 400B is similar to the embodiment of the system 400A and the embodiment of the system 100B. Herein, the housing 140B contains the liquid 103′ which forms the liquid film 103 on the wafer 101.

FIG. 4C shows a vertical cross-sectional view of an imaging system (hereinafter referred to as a system 400C) in accordance with some embodiments of the present disclosure. The embodiment of the system 400C is similar to the embodiment of the system 400A and the embodiment of the system 100C. Herein, a fraction of the wafer 101 is covered with a liquid film 104.

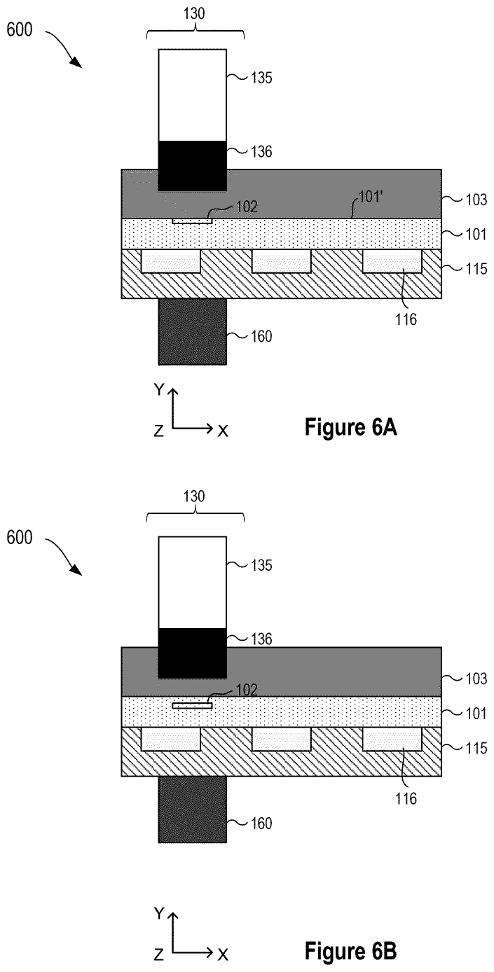

FIG. 5 shows a flow chart of an imaging process 500, in accordance with some embodiments of the present disclosure. At step S510, an objective lens of a microscope is immersed at least partially in a liquid film formed on a wafer. The objective lens is spaced apart from the wafer. The microscope includes a light source configured to emit light of one or more wavelengths. At step S520, a first image of a region within the wafer is captured using the one or more wavelengths. At step S530, the wafer is reoriented relative to or around the region by a robotic shaft, which includes tilting, rotating or both tilting and rotating the wafer around the region. At step S540, a second image of the region is captured using the one or more wavelengths.

FIGS. 6A, 6B and 6C show vertical cross-sectional views of an imaging system (hereinafter referred to as a system 600) at various intermediate steps of imaging, in accordance with some embodiments of the present disclosure. The system 600 can be the system 400A, 400B, 400C or the like. When the system 600 is the system 400A or 400B, some components (e.g. 107, 150, 140A/140B, 131 and 133) are omitted for simplicity purposes. Additionally, it should be understood that the imaging processes described in FIGS. 6A-6C using the liquid film 103 for illustration purposes are also applicable to the system 400C wherein the liquid film 104 is used.

In FIG. 6A, the wafer carrier 115 and the wafer 101 are in contact with each other. The vacuum cavities 116 can be on to create vacuum between the wafer carrier 115 and the wafer 101 or be off to create no vacuum. The microscope 130 can capture a first image of the region 102 of the wafer 101. As discussed earlier, the region 102 may be below the top surface 101′ of the wafer 101 by 0-1000 nm, and the present disclosure will be focused on defect analysis for illustrative purposes so the system 600 may also be referred to as a 3D defect imaging system.

In FIG. 6B, the microscope 130 is stationary while the robotic shaft 160 is elevated in the Z direction using magnetically controlled movement. The vacuum cavities 116 can be on to create vacuum between the wafer carrier 115 and the wafer 101. The vacuum cavity 161 (e.g. shown in FIG. 4D) can be on to create vacuum between the robotic shaft 160 and the wafer carrier 115. As a result, the wafer 101 can be elevated by the robotic shaft 160 so the region 102 imaged by the microscope 130 (or the image plane of the microscope 130) is relatively “moved” down, and the microscope 130 can capture a second image of the wafer 101 at a different Z position.

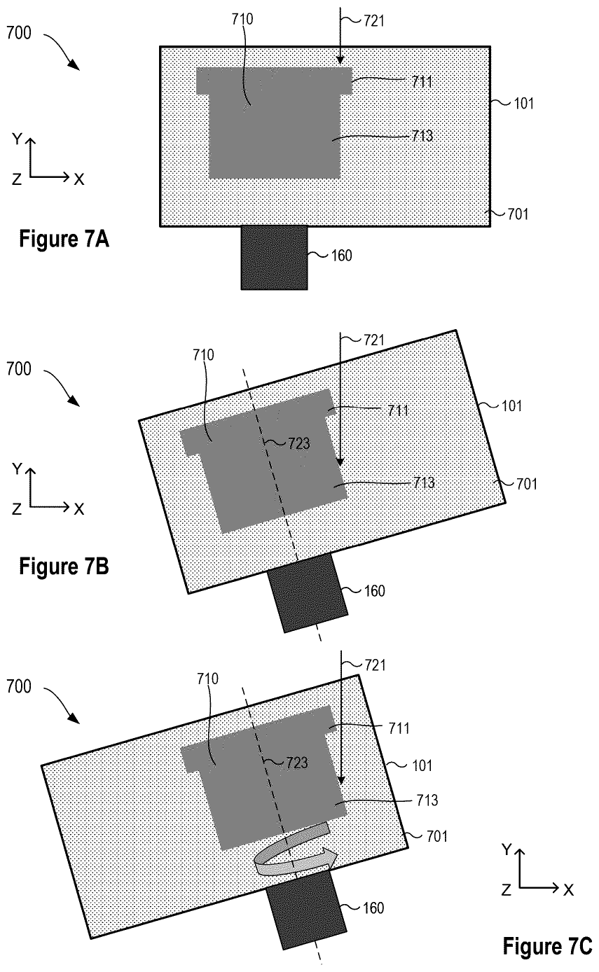

In FIG. 6C, the wafer 101 is tilted relative to or around the region 102 by the robotic shaft 160, and the microscope 130 can capture a third image of the wafer 101 at a tilted angle relative to the XY plane. The tilted angle is not particularly limited and can be larger than 0° and smaller than 90° e.g. 1°, 2°, 5°, 10°, 15°, 20°, 30°, 45°, 60°, 70°, 80°, 89° or any values therebetween. While shown to be tilted with the left part lower than the right part, it should be understood that the left part can be tilted to be higher than the right part as well, similar to FIG. 3C. Additionally, the wafer 101 may be rotated relative to or around the region 102, which will be further explained in detail in FIGS. 7A-7C.

The wafer 101 may be further tilted by tilting the robotic shaft 160. The wafer 101 may also be further moved up or down by moving the robotic shaft 160 up or down. The wafer 101 may further be tilted around a different region; or rather, the region 102 may be moved to a different location by moving the wafer 101 and/or the microscope 130 laterally in the XY plane. The microscope 130 can capture additional images of the wafer 101 at various X, Y and Z positions, various tilted angles as well as rotated positions.

FIGS. 7A, 7B and 7C show vertical cross-sectional views of an imaging system (hereinafter referred to as a system 700) at various intermediate steps of imaging, in accordance with some embodiments of the present disclosure. The system 700 can be the system 400A, 400B, 400C or the like, with some components (e.g. 107, 150, 140A/140B, 130, 103/104 and 115) omitted for simplicity purposes.

In FIG. 7A, the wafer 101 can include a dielectric material 701 and a structure 710 (e.g. a defect) embedded therein. The structure 710 includes a top structure 711 and a bottom structure 713. The top structure 711 is wider than the bottom structure 713 in the XY plane for example in the X direction. In some embodiments, the top structure 711 includes a metal material which can block a light 721 (e.g. an infrared light) that penetrates the dielectric material 701. As a result, the detector 133 may not accurately characterize the bottom structure 713.

In FIG. 7B, the wafer 101 is tilted by the robotic shaft 160 so that the light 721 is not blocked by the top structure 711. Accordingly, the light 721 can reach the bottom structure 713, and the detector 133 may capture an image of the bottom structure 713.

In FIG. 7C, the wafer 101 can be rotated around an inner axis 723 (e.g. a central axis) of the structure 710 by rotating the robotic shaft 160 so that the detector 133 may image a periphery or an entire sidewall of the bottom structure 713. Note that the inner axis 723 is relocated to be centered around the structure 710 to study the structure 710 in three dimensions. That is to say, while the inner axis 723 of the structure 710 is offset from a center of the wafer 101, the wafer 101 need not be rotated or tilted around the center of the wafer 101. Rather, the wafer 101 can be rotated or tilted around a point or an axis of the structure 710, preferably around a central point or a central axis of the structure 710. In addition, while the example of FIG. 7C shows a 180-degree rotation, any degree of rotation in any increment can be implemented. Particularly, a continuous scan of a 360-degree rotation can be implemented.

The structure 710 can include the aforementioned circuit elements or defects. When the structure 710 includes a defect, the top structure 711 and the bottom structure 713 may include a same material and thus form a seamless piece of the structure 710. In some embodiments, the top structure 711 and the bottom structure 713 may include different materials.

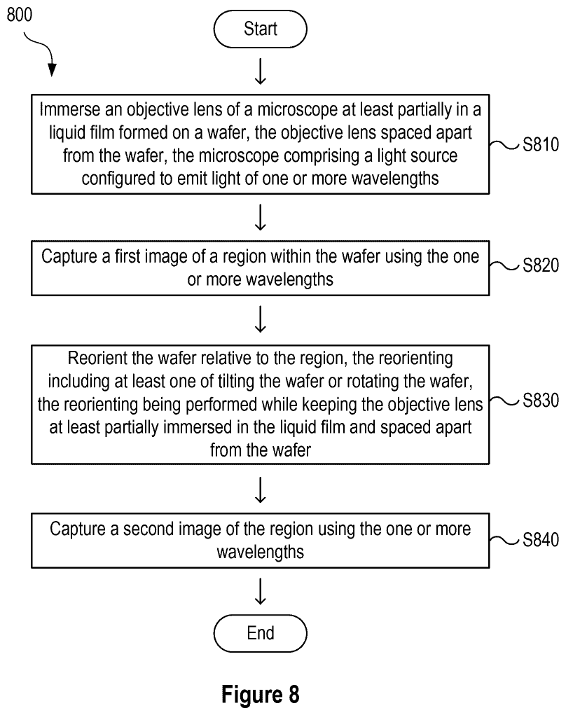

FIG. 8 shows a flow chart of an imaging process 800, in accordance with some embodiments of the present disclosure. At step S810, an objective lens of a microscope is immersed at least partially in a liquid film formed on a wafer. The objective lens is spaced apart from the wafer. The microscope includes a light source configured to emit light of one or more wavelengths. At step S820, a first image of a region within the wafer is captured using the one or more wavelengths. At step S830, the wafer is reoriented relative to or around the region, which includes at least one of tilting the wafer or rotating the wafer. The reorienting is performed while the objective lens is kept at least partially immersed in the liquid film and spaced apart from the wafer. At step S840, a second image of the region is captured using the one or more wavelengths.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of 3D imaging, the method comprising:
immersing an objective lens of a microscope at least partially in a liquid film formed on a wafer, the objective lens spaced apart from the wafer, the microscope comprising a light source configured to emit light of one or more wavelengths;
capturing a first image of a region within the wafer using the one or more wavelengths;
reorienting the wafer relative to the region, the reorienting including at least one of tilting the wafer or rotating the wafer, the reorienting being performed while keeping the objective lens at least partially immersed in the liquid film and spaced apart from the wafer; and
capturing a second image of the region using the one or more wavelengths.

2. The method of claim 1, wherein:
the reorienting the wafer comprises tilting the wafer relative to the region using magnetically controlled movement.

3. The method of claim 2, wherein:
the wafer is on a wafer carrier comprising a first magnet,
the wafer carrier is above a wafer chuck comprising a second magnet, and
at least one of the first magnet or the second magnet comprises an electromagnet.

4. The method of claim 3, wherein:
the electromagnet comprises separate electromagnetic units that are independent of each other, and
the tilting the wafer comprises flowing different electrical currents through the separate electromagnetic units to create a magnetic field gradient along a horizontal direction parallel to a top surface of the wafer chuck.

5. The method of claim 3, further comprising:
moving the wafer toward or away from the objective lens by adjusting an electrical current through the electromagnet; and
capturing a third image of the region using the one or more wavelengths while the objective lens is at least partially immersed in the liquid film and spaced apart from the wafer.

6. The method of claim 3, wherein:
the first magnet comprises a permanent magnet, and
the wafer chuck is an electrostatic chuck or reverse electrostatic chuck.

7. The method of claim 1, wherein:
the reorienting the wafer comprises tilting, rotating or both tiling and rotating the wafer relative to the region by a robotic shaft,
the wafer is on a wafer carrier, and
the wafer carrier is on the robotic shaft.

8. The method of claim 7, further comprising:
moving the wafer toward or away from the objective lens by moving the robotic shaft; and
capturing a third image of the region using the one or more wavelengths while the objective lens is at least partially immersed in the liquid film and spaced apart from the wafer.

9. The method of claim 7, wherein:
the robotic shaft is offset from a center of the wafer.

10. The method of claim 7, wherein:
the wafer carrier is movably attached to the robotic shaft, and
the wafer carrier is fixedly held on the robotic shaft during the reorienting the wafer.

11. The method of claim 7, wherein:
the wafer carrier includes at least one selected from the group consisting of a wafer pin, a clamp and a vacuum cavity, configured to hold the wafer, and
the robotic shaft includes at least one selected from the group consisting of a wafer pin, a clamp and a vacuum cavity, configured to hold the wafer carrier.

12. The method of claim 1, wherein the wafer comprises:
a dielectric material; and
a structure embedded in the dielectric material,
wherein the light of one or more wavelengths is configured to penetrate the dielectric material and reach the structure,
wherein the structure includes a top structure and a bottom structure, the top structure is configured to block the light of one or more wavelengths, and the top structure is wider than the bottom structure when viewed from above the top structure.

13. An imaging system, comprising:
a wafer carrier configured to receive a wafer and comprising a first magnet;
a wafer chuck comprising a second magnet, at least one of the first magnet or the second magnet comprising an electromagnet;
a microscope comprising a light source configured to emit light of one or more wavelengths, optics configured to direct the light to the wafer, and a detector configured to image the wafer, the optics comprising an objective lens configured for at least partial immersion in a liquid film formed on the wafer; and
a liquid supply mechanism configured to form the liquid film between the wafer and the objective lens,
wherein the detector is configured to image a region within the wafer while the objective lens is at least partially immersed in the liquid film and spaced apart from the wafer,
wherein the electromagnet comprises separate electromagnetic units that are independent of each other, and the separate electromagnetic units are configured to receive separate electrical currents to create a magnetic field gradient along a horizontal direction parallel to a top surface of the wafer chuck to tilt the wafer relative to the region.

14. The imaging system of claim 13, wherein:
the electromagnet is configured to move the wafer toward or away from the objective lens by receiving an electrical current to attract the wafer carrier to the wafer chuck or repel the wafer carrier from the wafer chuck while the wafer remains on the wafer carrier.

15. The imaging system of claim 13, wherein:
the liquid supply mechanism comprises a housing configured to contain a liquid to form the liquid film on the wafer, and
the liquid is stationary.

16. An imaging system, comprising:
a wafer carrier configured to receive a wafer;
a robotic shaft below the wafer carrier;
a microscope comprising a light source configured to emit light of one or more wavelengths, optics configured to direct the light to the wafer, and a detector configured to image the wafer, the optics comprising an objective lens configured for at least partial immersion in a liquid film formed on the wafer; and
a liquid supply mechanism configured to form the liquid film between the wafer and the objective lens,
wherein the detector is configured to image a region within the wafer while the objective lens is at least partially immersed in the liquid film and spaced apart from the wafer,
wherein the robotic shaft is configured to reorient the wafer relative to the region, by tilting the robotic shaft, rotating the robotic shaft or both so that the wafer tilts, rotates or both tilts and rotates around the region.

17. The imaging system of claim 16, wherein:
the robotic shaft is configured to move the wafer toward or away from the objective lens.

18. The imaging system of claim 16, wherein:
the wafer carrier is movably attached to the robotic shaft, and
the wafer carrier is fixedly held on the robotic shaft during the reorienting the wafer.

19. The imaging system of claim 16, wherein:
the wafer carrier includes at least one selected from the group consisting of a pin, a clamp and a vacuum cavity, configured to hold the wafer, and
the robotic shaft includes at least one selected from the group consisting of a pin, a clamp and a vacuum cavity, configured to hold the wafer carrier.

20. The imaging system of claim 16, wherein:
the liquid supply mechanism comprises a housing configured to contain a liquid to form the liquid film on the wafer, and
the liquid is stationary.
